(19) United States
(12) Patent Application Publication
(10) Pub. No.: US 2024/0224454 A1
(43) Pub. Date: Jul. 4, 2024

(54) DISPLAY DEVICE AND MANUFACTURING METHOD OF THE SAME

(71) Applicant: SAMSUNG DISPLAY CO., LTD., YONGIN-SI (KR)

(72) Inventors: WON-SEOK KIM, Yongin-si (KR); JONGDEOK PARK, Yongin-si (KR); INTAE SON, Yongin-si (KR); JAESUK YOO, Yongin-si (KR); KANG-WOO LEE, Yongin-si (KR); DASONG LEE, Yongin-si (KR)

(21) Appl. No.: 18/459,557

(22) Filed: Sep. 1, 2023

(30) Foreign Application Priority Data
Jan. 2, 2023 (KR) 10-2023-0000210

(51) Int. Cl. H05K 5/03

(52) U.S. Cl. CPC H05K 5/03

(57) ABSTRACT

A display device includes a window module disposed on a display module. The display module has a peripheral region disposed on at least one side of an active region. The window module includes a pattern layer disposed adjacent to a window and overlapping the active region and the peripheral region. The pattern layer includes a transparent portion and a discoloration portion having a light transmittance lower than that of the transparent portion. Each of the transparent portion and the discoloration portion includes a discoloration inducer activated by a laser, so that the display device exhibits good display quality and excellent reliability properties.

### CROSS-REFERENCE TO RELATED APPLICATIONS

This U.S. non-provisional patent application claims priority under 35 U.S.C. § 119 of Korean Patent Application No. 10-2023-0000210, filed on Jan. 2, 2023, the entire contents of which are hereby incorporated by reference.

### BACKGROUND

### 1. Technical Field

One or more embodiments described herein relate to a display device and a method for manufacturing a display device.

### 2. Description of the Related Art

Various types of display devices are used to provide image information. These devices include a display module and a window module for protecting a display surface of the display module. In order to prevent light leakage and to cover the lower structure of a non-display region, the window module may include a light-blocking pattern such as a black matrix (BM) as a separate layer from a window.

The light-blocking pattern may degrade display quality and reliability as a result of degradation in adhesion between the window and the display module. For example, a step may be formed between the light blocking pattern and the window, or un-curing of a portion overlapping the light-blocking pattern may occur when an adhesive layer attaching the display panel and the window is further cured with ultraviolet rays. These and/or other drawbacks may be corrected by embodiments described in greater detail below.

### SUMMARY

One or more embodiments described herein provide a display device having excellent reliability, achieved by excluding a separate light blocking pattern disposed on a lower surface of a window or by reducing the thickness of the light blocking pattern.

One or more embodiments described herein may also provide a method for manufacturing a display device including a window module having a low light transmittance region instead of a light blocking pattern.

An embodiment of the inventive concept provides a display device including a display module having an active region and a peripheral region disposed on at least one side of the active region, and a window module disposed on the display module. The window module includes a window and a pattern layer disposed adjacent to the window and overlapping the active region and the peripheral region. The pattern layer may include a transparent portion and a discoloration portion having a light transmittance lower than the transparent portion. The transparent portion and the discoloration portion may include a discoloration inducer activated by a laser.

In an embodiment, the discoloration inducer may include at least one of an organic pigment, an inorganic pigment, or a metal oxide.

In an embodiment, the pattern layer may include 0.05 wt % to 5 wt % of the discoloration inducer based on a total weight of the pattern layer.

In an embodiment, the transparent portion may include a base resin, wherein the discoloration portion may include a discoloration resin modified from the base resin.

In an embodiment, the pattern layer may be a single adhesive layer disposed between the display module and the window.

In an embodiment, the pattern layer may include a sub-pattern layer including the transparent portion and the discoloration portion, and a transparent adhesive layer disposed on at least one of an upper surface or a lower surface of the sub-pattern layer, and excluding the discoloration inducer.

In an embodiment, the sub-pattern layer may be a single adhesive layer.

In an embodiment, an optical density of the discoloration portion may be 1 to 3, and the optical density of the transparent portion may be less than 1.

In an embodiment, the pattern layer may be disposed in an upper portion of the window, and the window module may further include a window adhesive layer disposed between the display module and the window.

In an embodiment, the pattern layer may include a sub-pattern layer including the transparent portion and the discoloration portion, and a base film layer disposed on an upper surface of the sub-pattern layer, and not including the discoloration inducer.

In an embodiment, the pattern layer may include a sub-pattern layer including the transparent portion and the discoloration portion, and a protection layer adhesive layer disposed between the sub-pattern layer and the window, and excluding the discoloration inducer.

In an embodiment, the window module may further include a light blocking pattern disposed on an upper surface or a lower surface of the window, and overlapping the discoloration portion.

In an embodiment of the inventive concept, a display device includes an electronic module, a display module disposed on the electronic module, and a window module. The display module includes an active region, an electronic module region overlapping the electronic module and provided in the active region, and a peripheral region disposed on at least one side of the active region. The window module is disposed on the display module and includes a window and a pattern layer disposed adjacent to the window. The pattern layer includes a discoloration inducer activated by a laser. The pattern layer includes a transparent portion corresponding to the active region, and a discoloration portion corresponding to the peripheral region and having a higher optical density than the transparent portion.

In an embodiment, the pattern layer may overlap the electronic module region, include the discoloration inducer, and further include a sub-discoloration portion having a higher optical density than the transparent portion.

In an embodiment, the discoloration inducer may include at least one of an organic pigment, an inorganic pigment, or a metal oxide.

In an embodiment of the inventive concept, a method for manufacturing a display device includes providing a display module, providing a preliminary pattern layer including a discoloration inducer on the display module, providing a window on the preliminary pattern layer, and irradiating a laser onto the preliminary pattern layer to form a pattern layer. The pattern layer includes a discoloration portion having an increased optical density by the discoloration inducer and a transparent portion having an optical density lower than the discoloration portion.

In an embodiment, the method may further include, before the forming of the pattern layer, performing ultraviolet-curing on the preliminary pattern layer.

In an embodiment, the display module may include an active region and a peripheral region disposed on at least one side of the active region, wherein forming the pattern layer may include irradiating the laser onto the peripheral region.

In an embodiment, the preliminary pattern layer may include a base resin and the discoloration inducer dispersed in the base resin, and forming the pattern layer may include changing the light transmittance of the base resin by the discoloration inducer activated by the laser, thereby forming the discoloration portion. In an embodiment, the laser may be an Nd:YAG laser.

### BRIEF DESCRIPTION OF THE FIGURES

The accompanying drawings are included to provide further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a perspective view of a display device according to an embodiment of the inventive concept;

FIG. 2 is an exploded perspective view of a display device according to an embodiment of the inventive concept;

FIG. 3 is a cross-sectional view of a display device of an embodiment of the inventive concept;

FIG. 4 is a cross-sectional view showing a window module according to an embodiment of the inventive concept;

FIG. 5A is a cross-sectional view showing a window module according to an embodiment of the inventive concept, and FIG. 5B is a cross-sectional view showing a window module according to an embodiment of the inventive concept;

FIG. 6 is a cross-sectional view showing a window module according to an embodiment of the inventive concept;

FIG. 7A is a cross-sectional view showing a pattern layer according to an embodiment of the inventive concept, and FIG. 7B is a cross-sectional view showing a pattern layer according to an embodiment of the inventive concept;

FIG. 8 is a cross-sectional view showing a window module according to an embodiment of the inventive concept;

FIG. 9 is a cross-sectional view of a display device according to an embodiment of the inventive concept;

FIG. 10 is a cross-sectional view of a portion a display device according to an embodiment of the inventive concept;

FIG. 11 is a flowchart about a method for manufacturing a display device of an embodiment of the inventive concept; and

FIG. 12A to FIG. 12D are views each schematically showing operations included in a method for manufacturing a display device of an embodiment of the inventive concept.

### DETAILED DESCRIPTION

The inventive concept may be modified in many alternate forms, and thus specific embodiments will be exemplified in the drawings and described in detail. It should be understood, however, that it is not intended to limit the inventive concept to the particular forms disclosed, but rather, is intended to cover all modifications, equivalents, and alternatives falling within the spirit and scope of the inventive concept.

In the present disclosure, when an element (or a region, a layer, a portion, and the like) is referred to as being “on,” “connected to,” or “coupled to” another element, it means that the element may be directly disposed on/connected to/coupled to the other element, or that a third element may be disposed therebetween.

Meanwhile, in the present disclosure, being “directly disposed” may mean that there is no layer, film, region, plate, or the like added between a portion of a layer, a film, a region, a plate, or the like and other portions. For example, being “directly disposed” may mean being disposed without additional members such as an adhesive member between two layers or two members.

Like reference numerals refer to like elements. Also, in the drawings, the thickness, the ratio, and the dimensions of elements are exaggerated for an effective description of technical contents. The term “and/or,” includes all combinations of one or more of which associated components may define.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the present invention. The terms of a singular form may include plural forms unless the context clearly indicates otherwise.

In addition, terms such as “below,” “lower,” “above,” “upper,” and the like are used to describe the relationship of the components shown in the drawings. The terms are used as a relative concept and are described with reference to the direction indicated in the drawings. In the present disclosure, being “disposed on” may not only include the case of being disposed in an upper portion of any one member but also the case of being disposed in a lower portion thereof.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the inventive concept pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

Hereinafter, a display device and a method for manufacturing a display device according to an embodiment of the inventive concept will be described with reference to the accompanying drawings.

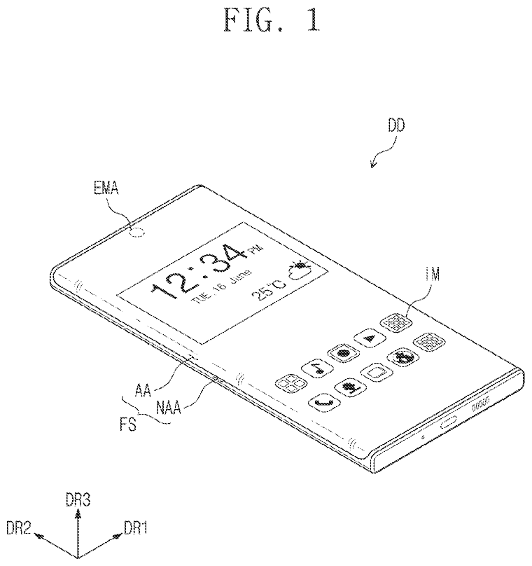

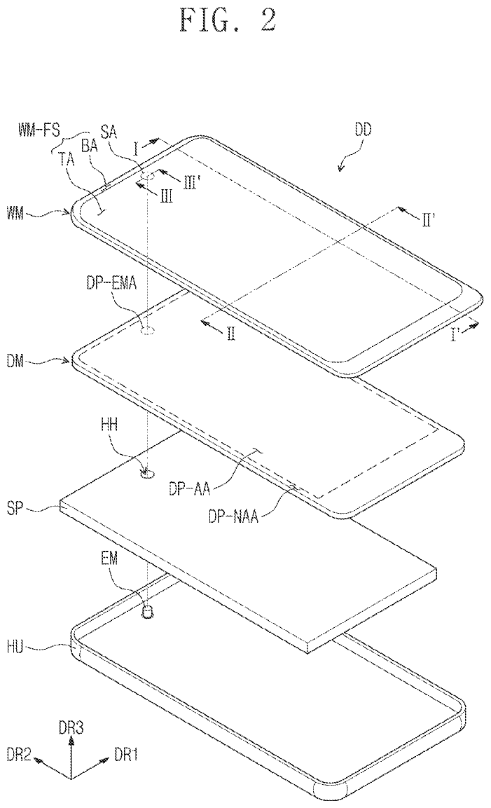

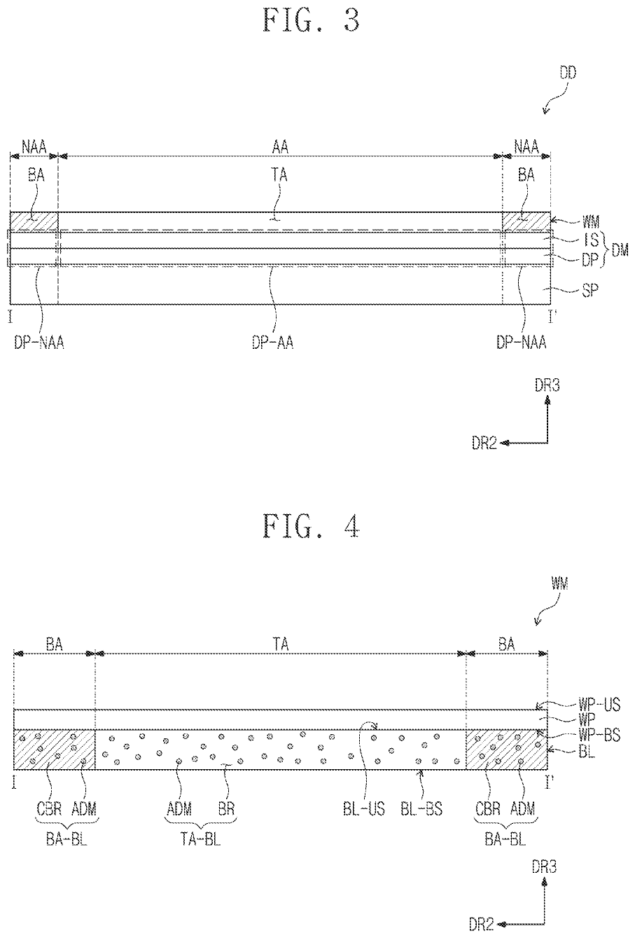

FIG. 1 is a perspective view showing a display device according to an embodiment of the inventive concept. FIG. 2 is an exploded perspective view of a display device according to an embodiment of the inventive concept. FIG. 3 is a cross-sectional view of a display device according to an embodiment of the inventive concept, and FIG. 4 is a cross-sectional view of a window module according to an embodiment of the inventive concept. FIG. 3 is a cross-sectional view corresponding to line I-I′ of FIG. 1, and FIG. 4 is a cross-sectional view of a window module included in FIG. 3.

Referring to FIG. 1 and FIG. 2, an electronic device including a display device DD may, in accordance with one embodiment, be activated based on an electrical signal. For example, the display device DD may be a mobile phone, a tablet, a car navigation system, a game console, or a wearable device, to name a few. In FIG. 1, the display device DD is illustrated as a mobile phone as one example of an electronic device which includes the display device DD.

The display device DD according to an embodiment may provide an image IM to a user through a display surface FS. The display surface FS may display an image through an active region AA. In addition, the display device DD according to an embodiment may sense an external input. The external input may include various forms of inputs provided from outside of the display device DD.

The active region AA may include a plane which extends along a first direction axis DR1 and a second direction axis DR2. The active region AA may further include a curved surface bent from at least one side of the plane defined by the first direction axis DR1 and the second direction axis DR2. The display device DD of an embodiment illustrated in FIG. 1 is illustrated as including two curved surfaces respectively bent from both sides of the plane defined by the first direction axis DR1 and the second direction axis DR2. However, the shape of the active region AA is not limited thereto. For example, the active region AA may include only the above plane, or the active region AA may further include curved surfaces bent from at least two, for example, three or four curved surfaces bent from three or four side surfaces of the plane, respectively. In addition, a display in a deformed shape other than a flat surface may be included even in a central portion of the active region AA, rather than on one side of a plane.

Referring to FIG. 1 and FIG. 2, the display device DD may include the active region AA and a peripheral region NAA adjacent to the active region AA. The peripheral region NAA is a region which blocks optical signals and, for example, may be a region disposed on an outer side of the active region AA and partially or completely surrounding the active region AA. However, the embodiment of the inventive concept is not limited thereto. For example, the peripheral region NAA may be disposed on at least one side of the active region AA. In addition, unlike what is illustrated in FIG. 1, the active region AA of the display device DD may, according to an embodiment, have various shapes. A rectangular shape is shown as one example, but the shape may be different from a rectangle in other embodiments. In one embodiment, the shape of the active region AA may be determined according to the disposition of the peripheral region NAA adjacent thereto.

The active region AA may be a portion corresponding to an active region DP-AA of a display module DM to be described in greater detail below. The peripheral region NAA may be a portion corresponding to a peripheral region DP-NAA of the display module DM. The active region AA may be referred to as a display region, and the peripheral region NAA may be referred to as a non-display region.

Meanwhile, in FIG. 1 and the following drawings, a first direction axis DR1 to a third direction axis DR3 are illustrated. The directions indicated by the first to third direction axes DR1, DR2, and DR3 described in the present specification are relative concepts, and may be converted into different directions. In addition, the directions indicated by the first to third direction axes DR1, DR2, and DR3 may be described as first to third directions, and may be denoted by the same reference numerals.

In the present specification, the first direction axis DR1 and the second direction axis DR2 are perpendicular to each other, and the third direction axis DR3 may be a normal direction with respect to a plane defined by the first direction axis DR1 and the second direction axis DR2. In the present specification, a front surface (or an upper surface, an upper portion, or an upper side) and a back surface (or a lower surface, a lower portion, or a lower side) of members constituting the display device DD may be defined with respect to the third direction axis DR3.

An electronic module region EMA may be included in the active region AA of the display device DD. The electronic module region EMA of the display device DD may be a portion corresponding to and aligned with an electronic module region DP-EMA of the display module DM. FIG. 1 exemplarily illustrates one electronic module region EMA, but one or more additional electronic module regions EMA may be included in other embodiments. The electronic module region EMA may be a portion of (or included in) the active region AA. In an embodiment, the display device DD may also display an image in the electronic module region EMA. When electronic modules disposed in the electronic module region EMA are deactivated, the electronic module region EMA may display corresponding portions of an image as a display surface.

Various electronic modules EM may be disposed in the electronic module region EMA. An electronic module EM may receive an external input transmitted through the electronic module region EMA, or may provide an output through the electronic module region EMA. For example, the electronic module EM may include at least one of a camera, a speaker, a light sensing sensor, or a heat sensing sensor. The electronic module region EMA may sense an external object received through the display surface FS, or may provide a sound signal such as voice to the outside through the display surface FS. The electronic module EM may include a plurality of components, but is not limited to any one embodiment.

Meanwhile, the form of the display device DD of an embodiment is not limited to what are illustrated in FIG. 1. Also, the display device DD of an embodiment may be flexible in that it may be folded, bent, or rolled. For example, the display device according to an embodiment is not limited to a case in which the display surface FS is mostly a flat surface, and may include a portion with at least one curved surface as a main display surface, or may include a folding region in which a display surface is folded with respect to at least one folding axis.

The display device DD of an embodiment may include the display module DM and a window module WM disposed in an upper portion of the display module DM. In addition, the display device DD of an embodiment may include an electronic module EM disposed in a lower portion (along axis DR3) of the display module DM. Meanwhile, the display device DD of an embodiment may include a lower module SP disposed on a lower side of the display module DM and a housing HU for accommodating the display module DM and the lower module SP. The housing HU may be coupled to the window module WM.

The window module WM may be disposed in the upper portion of the display module DM to cover the all or a portion of the upper surface of the display module DM. The window module WM may have a shape corresponding to the shape of the display module DM.

The window module WM may include a transmission region TA and a bezel region BA. A front surface WM-FS of the window module WM including the transmission region TA and the bezel region BA corresponds to a front surface FS of the display device DD. A user may visually recognize an image transmitted through the transmission region TA corresponding to the display surface FS of the display device DD.

The transmission region TA may be an optically transparent region. The bezel region BA may be a region having relatively low light transmittance compared to the transmission region TA. The bezel region BA may have a predetermined color. The bezel region BA is adjacent to the transmission region TA, and may surround the transmission region TA. The bezel region BA may define the shape of the transmission region TA. However, the embodiment of the inventive concept is not limited to what is illustrated. For example, the bezel region BA may be disposed adjacent to only one or some sides of the transmission region TA, or a portion of the bezel region BA may be omitted. In an embodiment, the bezel region BA corresponds to the peripheral region DP-NAA of the display module DM, and may define the peripheral region NAA of the display device DD.

In an embodiment, the window module WM may include a sensing region SA. The sensing region SA may be a region overlapping the electronic module EM. The sensing region SA may be a region overlapping the electronic module region DP-EMA of the display module DM. In addition, the sensing region SA may be a region corresponding to the electronic module region EMA of the display device DD. The display device DD may receive an external signal for the electronic module EM through the sensing region SA of the window module WM, or may provide a signal output from the electronic module EM to the outside. In an embodiment, the sensing region SA may be defined in the transmission region TA.

The display module DM included in the display device DD of an embodiment may be configured to generate an image and sense an input applied from the outside. Referring to FIG. 3, the display module DM according to an embodiment may include a display panel DP and an input sensor IS disposed on the display panel DP. In addition, the display module DM of an embodiment may further include an optical layer disposed on the input sensor IS.

The display panel DP may substantially generate an image. The display panel DP may be a light emitting-type display panel. For example, the display panel DP may be an organic light emitting display panel, an inorganic light emitting display panel, a quantum-dot display panel, a micro-LED display panel, or a nano-LED display panel. The display panel DP may be referred to as a display layer.

The input sensor IS may be disposed on the display panel DP. The input sensor IS may sense an external input, such as, for example, contact from a finger of a user or a stylus. The input sensor IS may be formed on the display panel DP through a continuous process. In this case, the input sensor IS may be described as being directly disposed on the display panel DP. Being directly disposed may mean that a third element is not disposed between the input sensor IS and the display panel DP. For example, a separate adhesive member may not be disposed between the input sensor IS and the display panel DP. In one embodiment, the input sensor IS and the display panel DP may be coupled to each other through an adhesive member. The adhesive member may include a typical adhesive or a pressure-sensitive adhesive.

The optical layer may be disposed on the input sensor IS. The optical layer may be, for example, an anti-reflection layer which reduces the reflectance by external light incident from the outside of the display module DM. The optical layer may be formed on the input sensor IS through a continuous process. The optical layer may include a polarizing plate or a color filter layer.

Referring to FIG. 2, the lower module SP may be disposed on the lower side of the display module DM. The lower module SP may include at least one of a support plate, a cushion layer, a blocking layer, a filling layer, or an interlayer bonding layer. The lower module SP may support the display module DM, or may prevent the deformation of the display module DM caused by external impact or an application of force.

In an embodiment, the lower module SP may have a through-hole HH formed therein. The through-hole HH may overlap or correspond to (aligned with) the electronic module region EMA of the display device DD. The through-hole HH may therefore overlap the electronic module EM. At least a portion of the electronic module EM may be inserted into the through-hole HH. When the lower module SP is provided in a form in which a plurality of members are stacked, the through-hole HH may be included in only some of the members of the lower module SP.

In an embodiment, the window module WM may include a window WP, and a pattern layer BL disposed in an upper portion or lower portion of the window WP. The pattern layer BL may serve as an adhesive layer disposed either in an upper portion or lower portion of the window WP, or as a protection layer.

FIG. 4 illustrates an embodiment in which the pattern layer BL is disposed on a lower surface WP-BS of the window WP. For example, in the embodiment illustrated in FIG. 4, the pattern layer BL may serve as an adhesive layer. However, the embodiment of the inventive concept is not limited thereto, and the pattern layer BL may be disposed on an upper surface WP-US of the window WP, and the pattern layer BL may not have adhesion force.

In an embodiment, the window WP may include an optically transparent insulation material. The window WP may be a glass substrate or a plastic substrate. For example, the window WP may be an enhanced tempered glass substrate. In addition, the window WP may be thin enough to allow a folding operation to be performed.

In one embodiment, the window WP may be an ultra-thin glass (UTG) substrate. The window WP may be made of a glass material and used as a cover window in a display device. In one embodiment, the window WP may be formed of a polymer resin having flexibility. For example, the window WP may be made of polyimide, polyacrylate, polymethylmethacrylate, polycarbonate, polyethylenenaphthalate, polyvinylidene chloride, polyvinylidene difluorid, polystyrene, an ethylene vinylalcohol copolymer, or a combination thereof. However, the embodiment of the inventive concept is not limited thereto, and any type of window may be used as a cover window.

The pattern layer BL may include a transparent portion TA-BL and a discoloration portion BA-BL. Referring to FIG. 3 and FIG. 4, the pattern layer BL may overlap the active region DP-AA and the peripheral region DP-NAA of the display module DM. In addition, the transparent portion TA-BL of the pattern layer BL may correspond to the transmission region TA, and the discoloration portion BA-BL of the pattern layer BL may correspond to the bezel region BA.

The discoloration portion BA-BL of the pattern layer BL may have a lower light transmittance than the transparent portion TA-BL. For example, the light transmittance of the transparent portion TA-BL may be 90% or higher, and the light transmittance of the discoloration portion BA-BL may be 50% or lower. Meanwhile, the light transmittance of the pattern layer BL may be the light transmittance of visible light.

In an embodiment, the pattern layer BL including the discoloration portion BA-BL having a low light transmittance may cover the peripheral region DP-NAA of the display module DM to serve as a light blocking layer or a cover layer. In addition, the transparent portion TA-BL has relatively high light transmittance, and accordingly the display quality of the display device DD in the active region AA may be excellent.

In an embodiment, the optical density of the pattern layer discoloration portion BA-BL may be greater than the optical density of the transparent portion TA-BL. For example, the optical density of the discoloration portion BA-BL may be 1 to 3, where an optical density of 1 blocks less light (allows more light to pass through) and an optical density of 3 blocks more light (allows less light to pass through). For example, when the optical density is less than 1, the discoloration portion BA-BL has a degraded light-blocking degree and thus cannot effectively serve as a light blocking layer. Meanwhile, when the optical density is 3, components of the peripheral region DP-NAA of the display module DM may be sufficiently covered without light leakage by the discoloration portion BA-BL. Compared to the discoloration portion BA-BL, the optical density of the transparent portion TA-BL may be less than 1. The transparent portion TA-BL may maintain a low optical density, thereby maintaining good display quality of the display device DD. While the optical density range of 1 to 3 is suitable for many applications, the optical density values of the discoloration portion BA-BL and/or the transparent portion TA-BL may have different values (e.g., values in a different range) in other embodiments.

In an embodiment, the pattern layer BL may include a discoloration inducer ADM. The discoloration inducer ADM may be included in both the transparent portion TA-BL and the discoloration portion BA-BL. The discoloration inducer ADM may be randomly dispersed in both the transparent portion TA-BL and the discoloration portion BA-BL. In an embodiment, the transparent portion TA-BL may exhibit high light transmittance properties while including the discoloration inducer ADM. In another embodiment, the concentration of the discoloration inducer ADM may be different in the transparent portion TA-BL and the discoloration portion BA-BL, e.g., the concentration of the discoloration inducer ADM may be greater in the discoloration portion BA-BL than the concentration of discoloration inducer ADM in the transparent portion TA-BL.

The discoloration inducer ADM may be a material activated by a laser. The discoloration inducer ADM may be an organic material or an inorganic material activated by a laser. When the laser is provided to the discoloration inducer ADM, the discoloration inducer ADM may be activated and release heat. The released thermal energy may induce thermal deformation of a surrounding material. Accordingly, in a portion including the discoloration inducer ADM and provided with a laser, the light transmittance may be lowered and the optical density may be increased comparing to the previous state the laser is not provided.

The discoloration inducer ADM may be an organic pigment, an inorganic pigment, or a metal oxide. For example, the discoloration inducer ADM may include at least one of an organic pigment such as an azo pigment having an azo group and a polycyclic pigment having a polycyclic group, an inorganic pigment including an oxide such as Sn or Sb, or a pigment including a metal oxide such as SiO₂, TiO₂, ZrO₂, V₂O₅, ZnO, or Al₂O₃. For example, an embodiment may include at least one of SiO₂, Al₂O₃, TiO₂, or ZrO₂ as the discoloration inducer ADM.

The discoloration inducer ADM may be included in a predetermined range (e.g., 0.05 wt % to 5 wt %) based on the total weight of the pattern layer BL. When the discoloration inducer ADM is included in less than 0.05 wt % based on the total weight of the pattern layer BL, the discoloration of a material by the discoloration agent ADM may not be sufficiently achieved. In this case, the discoloration portion BA-BL may not sufficiently perform a light blocking or covering function. In addition, when the discoloration inducer ADM is included in greater than 5 wt % based on the total weight of the pattern layer BL, the light transmittance of the transparent portion TA-BL is lowered, so that the display quality of the display device may be degraded. While the 0.05 wt % to 5 wt % may apply to some applications, the discoloration inducer ADM may be included in a different range in other embodiments.

In an embodiment, the thickness of the pattern layer BL may be lie within a predetermined range, e.g., 5 μm to 200 μm for some applications. When the thickness of the pattern layer BL is less than 5 μm, the ability to function as an adhesive layer for coupling members in an upper portion and a lower portion of the pattern layer BL to each other, or the ability to function as a protection member for protecting the members in the upper portion and the lower portion of the pattern layer BL, may be degraded. On the other hand, when the thickness of the pattern layer BL is greater than 200 μm, the overall thickness of the window module WM is increased, which, in turn, increases the thickness of the display device DD. In addition, when the thickness of the pattern layer BL is greater than 200 μm, the light transmittance of the window module WM may be lowered as a result of an increase in the thickness of the window module WM. As a result, display quality of the display device DD may be degraded. The range of 5 μm to 200 μm is given as an example. In one embodiment, the thickness of pattern layer BL may lie in a range different from 5 μm to 200 μm for other applications.

In one embodiment, the pattern layer BL may be provided with a thickness of 5 μm to 200 μm, and the content of the discoloration inducer ADM included in the pattern layer BL may vary according to the thickness. The content of the discoloration inducer ADM included in the pattern layer BL may be adjusted in the weight range of 0.05 wt % to 5 wt % to satisfy optical properties, such as the optical density of the discoloration portion BA-BL and the light transmittance of the transparent portion TA-BL in the pattern layer BL having a corresponding thickness.

The transparent portion TA-BL of the pattern layer BL may include a base resin BR and the discoloration inducer ADM, and the discoloration portion BA-BL may include a discoloration resin CBR and the discoloration inducer ADM. The discoloration resin CBR may be modified from the base resin BR.

The base resin BR and the discoloration resin CBR may include at least one of an acrylic resin, a polyethylene-based resin, a silicone-based resin, or a urethane-based resin. The base resin BR and the discoloration resin CBR may be polymer resins including at least one of the above-described resins. The discoloration resin CBR may be a polymer resin modified from the base resin BR. Since the base resin BR is provided with thermal energy induced from the discoloration inducer ADM, the arrangement of polymers in the base resin BR may be modified to exhibit optical properties in which light transmittance is lowered as the discoloration resin CBR. For example, the base resin BR and the discoloration resin CBR may include polymer materials of the same component, but properties such as the arrangement of polymers or the molecular weight of the polymers may be different from each other.

The discoloration inducer ADM may be dispersed in the base resin BR in the transparent portion TA-BL, and dispersed in the discoloration resin CBR in the discoloration portion BA-BL. The discoloration inducer ADM may be dispersed in the base resin BR or the discoloration resin CBR in the form of particles. Meanwhile, as previously indicated, in an embodiment the degree of dispersion of the discoloration inducer ADM in the discoloration portion BA-BL and the degree of dispersion of the discoloration inducer ADM in the transparent portion TA-BL may be different from each other. For example, the discoloration inducer ADM in the discoloration portion BA-BL (which is the state after the laser is irradiated) may be dispersed in a form of being aggregated with each other. Depending on the dispersion form of the discoloration inducer ADM, the optical density of the discoloration portion BA-BL may be further increased.

In an embodiment, the pattern layer BL may overlap the entire window WP. Both a lower surface WP-BS and an upper surface WP-US of the window WP may be flat surfaces without including a step or other discontinuity. In addition, both an upper surface BL-US and a lower surface BL-BS of the pattern layer BL may also flat surfaces without including a step. Accordingly, the window WP and the pattern layer BL may be coupled to each other without separation that would otherwise occur if a step were formed.

In an embodiment, the pattern layer BL may overlap the window WP in the entire transmission region TA of the window WP and a portion (e.g., most) of the bezel region BA. Unlike what is illustrated in the drawings, in one embodiment, an edge of the pattern layer BL and an edge of the window WP may not match. For example, a portion of an edge portion of the bezel region BA spaced from the transmission region TA in the pattern layer BL may not overlap the window WP. However, even in the above case, no step (or other discontinuity) is formed between the lower surface WP-BS of the window WP and the pattern layer BL at the boundary between the bezel region BA and the transmission region TA. Thus, the pattern layer BL and the window WP may be coupled to each other without separation.

In an embodiment, the pattern layer BL may be an adhesive layer for coupling members in (or adjacent to) an upper portion or a lower portion of the pattern layer BL to each other. Excellent adhesion may be exhibited in both the transparent portion TA-BL and the discoloration portion BA-BL of the pattern layer BL. For example, when introducing an adhesive layer to bond the window WP and the display module DM during a display device manufacturing process, additional curing may be performed by irradiating an upper side of the window WP with ultraviolet rays after providing the adhesive layer. At this time, when there is a light blocking pattern in the window WP, an adhesive layer on a lower side of the light blocking pattern may not be cured. In the case of the display device DD of an embodiment, the pattern layer BL serving as an adhesive layer is provided on one surface of the window WP, and a portion of the pattern layer BL is discolored after ultraviolet curing to form the discoloration portion BA-BL. As a result, the problem of degradation in adhesion due to uncuring may be solved. Therefore, by including the window module WM having the pattern layer BL which includes the discoloration inducer ADM, the display device DD may exhibit good display quality and may exhibit excellent reliability properties, even though a separate light-blocking pattern is excluded.

In an embodiment, the pattern layer BL may be a single adhesive layer disposed between the display module DM and the window WP. The base resin BR and the discoloration resin CBR of the pattern layer BL may be an adhesive resin having good adhesion to both the display module DM and the window WP. The pattern layer BL may be directly disposed between the upper surface of the display module DM and the lower surface WP-BS of the window WP to fix the window module WM to the display module DM and serve as a light blocking pattern layer which defines the peripheral region NAA (e.g., see FIG. 3).

Meanwhile, the window module WM according to an embodiment may further include a protection layer disposed on the window WP. The protection layer may be disposed on the upper side of the window WP to protect the window WP from an external environment. The protection layer is transparent. Thus, even when the protection layer is disposed, image information provided by the display module DM may be identified. For example, the protection layer may include a base film and an adhesive layer for attaching the base film to the window WP. Meanwhile, in an embodiment, in addition to the pattern layer BL, the protection layer may further include a layer having a discoloration portion including a discoloration inducer as the pattern layer BL.

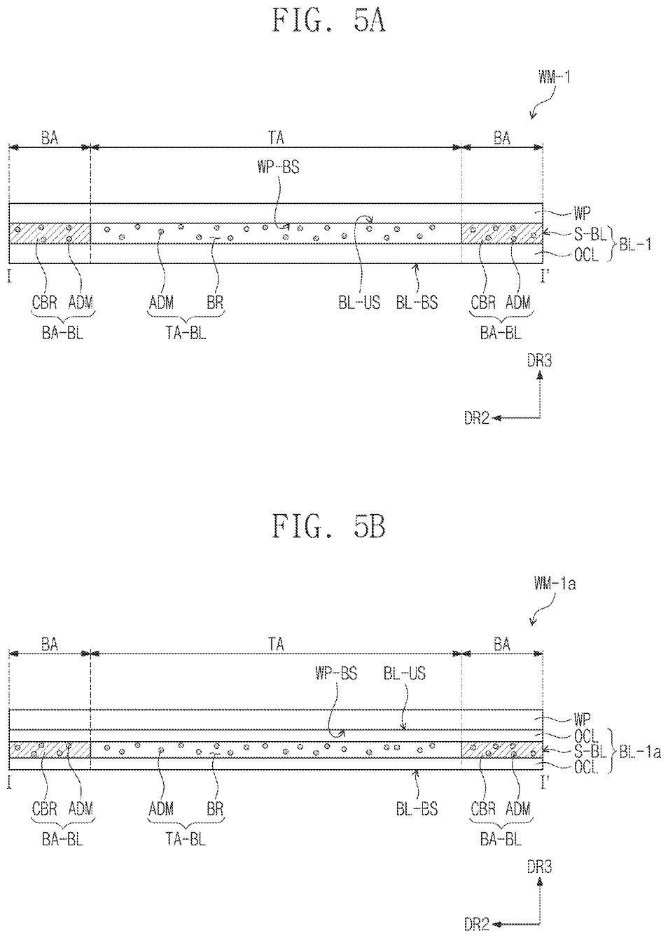

FIG. 5A to FIG. 8 are cross-sectional views of a window module according to an embodiment or a pattern layer according to an embodiment. Hereinafter, in describing FIG. 5A to FIG. 8, the same contents as those described with reference to FIG. 1 to FIG. 4 will not be described again, and instead differences will be mainly described.

Referring to FIG. 5A and FIG. 5B, window modules WM-1 and WM-1a according to an embodiment may include a window WP and pattern layers BL-1 and BL-1a respectively disposed on a lower side of the window WP. The pattern layers BL-1 and BL-1a may serve as adhesive layers for coupling the window WP and the display module DM (e.g., see FIG. 3).

In an embodiment illustrated in FIG. 5A and FIG. 5B, each of the pattern layers BL-1 and BL-1a may include a sub-pattern layer S-BL. In addition, a transparent adhesive layer OCL disposed on at least one of an upper surface or a lower surface of the pattern layers BL-1 and BL-1a may be included. Thus, when compared to the pattern layer BL illustrated and described in FIG. 4, the pattern layers BL-1 and BL-1a of an embodiment illustrated in FIG. 5A and FIG. 5B may include a plurality of stacked layers.

In an embodiment, the sub-pattern layer S-BL may include a transparent portion TA-BL and a discoloration portion BA-BL including a discoloration inducer ADM, and may include a transparent adhesive layer OCL which does not include a discoloration inducer. The same contents as the contents described with respect to the transparent portion TA-BL and the discoloration portion BA-BL in the pattern layer BL described with reference to FIG. 4 may be applied to the transparent portion TA-BL and the discoloration portion BA-BL of the sub-pattern layer S-BL.

The transparent adhesive layer OCL may include an optically clear adhesive. The transparent adhesive layer OCL may include at least one of an acrylic adhesive, a silicone-based adhesive, or a urethane-based adhesive.

Referring to FIG. 5A, the pattern layer BL-1 may include the sub-pattern layer S-BL attached to the window lower surface WP-BS and the transparent adhesive layer OCL disposed on a lower surface of the sub-pattern layer S-BL. In an embodiment of the window module WM-1 illustrated in FIG. 5A, both the sub-pattern layer S-BL and the transparent adhesive layer OCL may serve as an adhesive member. One surface of the sub-pattern layer S-BL (which is an upper surface BL-US of the pattern layer BL-1) is attached to the window WP, and one surface of the transparent adhesive layer OCL (which is a lower surface BL-BS of the pattern layer BL-1) may be attached to the display module DM (e.g., see FIG. 3). Thus, in an embodiment, the sub-pattern layer S-BL may be a single adhesive layer.

Referring to FIG. 5B, the pattern layer BL-1a may include a sub-pattern layer S-BL and a transparent adhesive layer OCL disposed on each of an upper surface and a lower surface of the sub-pattern layer S-BL. In an embodiment of the window module WM-1a illustrated in FIG. 5B, the sub-pattern layer S-BL may not have adhesion properties, and the transparent adhesive layers OCL may serve as adhesive members. The sub-pattern layer S-BL may be fixed between the transparent adhesive layers OCL disposed on the upper surface and the lower surface.

In the window module WM-1a according to an embodiment illustrated in FIG. 5B, an upper surface BL-US and a lower surface BL-BS of the pattern layer BL-1a are respectively one surface of each of the transparent adhesive layers OCL, and may be attached to corresponding ones of the window WP and the display module DM (e.g., see FIG. 3). Meanwhile, the embodiment of the inventive concept is not limited thereto, and the sub-pattern layer S-BL may serve as an adhesive layer as described with reference to FIG. 5A.

The window modules WM-1 and WM-1a according to an embodiment described with reference to FIG. 5A and FIG. 5B may further include a protection layer disposed in an upper portion of the window WP, in addition to the pattern layers BL-1 and BL-la as described with reference to FIG. 4.

The window modules WM-1 and WM-1a of the embodiments illustrated in FIG. 5A and FIG. 5B may be used as window modules of the display device DD described with reference to FIG. 1 to FIG. 3. Each of the window modules WM-1 and WM-1a may include a discoloration portion BA-BL including a discoloration inducer ADM, and may respectively include pattern layers BL-1 and BL-1a attached without a step (or other discontinuity) in the window WP, e.g., the pattern layers BL-1 and BL-1a may have even (or level) upper and lower surfaces. Thus, the window modules WM-1 and WM-1a may exhibit good display quality and improved reliability properties.

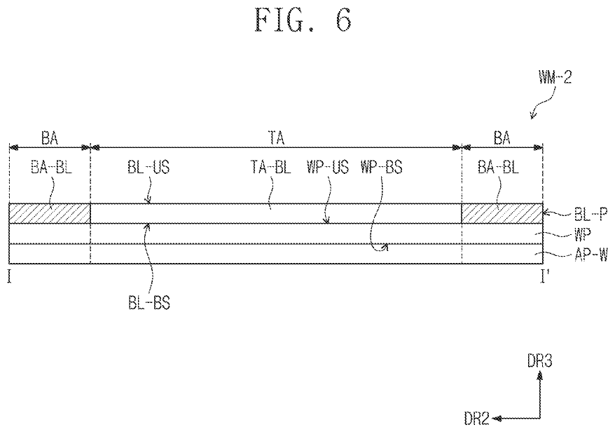

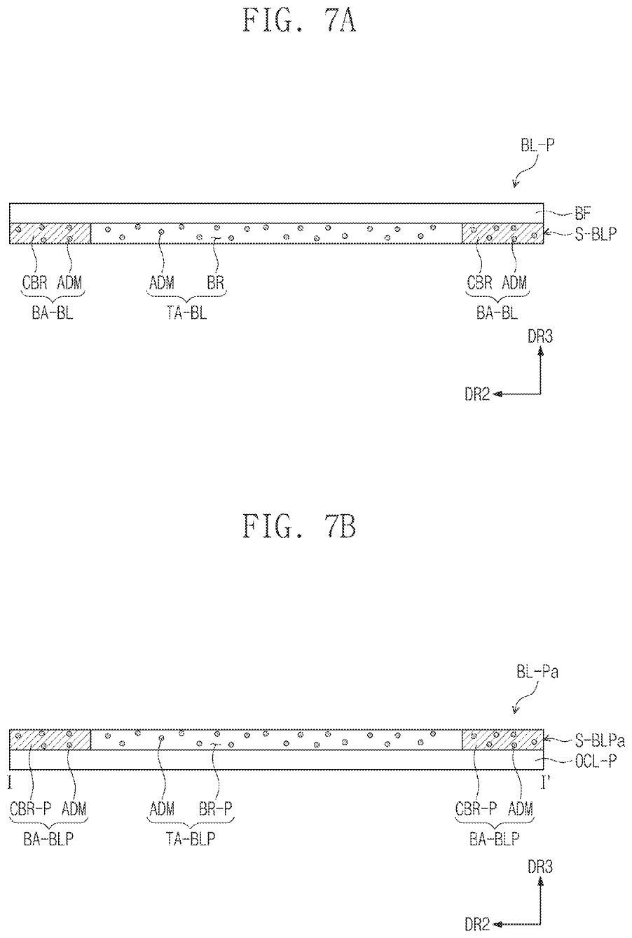

FIG. 6 is a cross-sectional view of a window module according to an embodiment of the inventive concept. FIG. 7A and FIG. 7B are each a cross-sectional view of a pattern layer according to an embodiment of the inventive concept. The pattern layers illustrated in FIG. 7A and FIG. 7B may be an embodiment of a pattern layer included in the window module of FIG. 6.

Referring to FIG. 6, a window module WM-2 according to an embodiment may include a window WP and a pattern layer BL-P disposed in an upper portion of the window WP. In addition, the window module WM-2 may further include a window adhesive layer AP-W disposed in a window lower surface WP-BS. The window adhesive layer AP-W may be disposed between the window WP of the window module WM-2 and the display module DM (e.g., see FIG. 3). The window adhesive layer AP-W may serve as a bonding layer for coupling the window module WM-2 and the display module DM (e.g., see FIG. 3).

The window adhesive layer AP-W may include an optically clear adhesive (OCA). The window adhesive layer AP-W may include at least one of an acrylic adhesive, a silicone-based adhesive, or a urethane-based adhesive.

In an embodiment, the pattern layer BL-P disposed on a window upper surface WP-US may include a transparent portion TA-BL and a discoloration portion BA-BL. The pattern layer BL-P disposed on the window upper surface WP-US may serve as a protection layer disposed on the window WP. The pattern layer BL-P disposed on the window WP may be disposed on an upper side of the window WP to protect the window WP from external impact, debris, etc. In addition, the pattern layer BL-P may correspond to the peripheral region NAA (e.g., see FIG. 3), may include the transparent portion TA-BL and the discoloration portion BA-BL, and may serve as a light blocking pattern layer by covering the peripheral region DP-NAA of the display module DM.

Referring to FIG. 7A, the pattern layer BL-P according to an embodiment may include a sub-pattern layer S-BLP and a base film layer BF. The sub-pattern layer S-BLP may be disposed on a lower side of the base film layer BF. The sub-pattern layer S-BLP may be a layer adjacent to the window upper surface WP-US (e.g., see FIG. 6) of the window.

The sub-pattern layer S-BLP may include the transparent portion TA-BL including a discoloration inducer ADM and a base resin BR, and the discoloration portion BA-BL may include a discoloration inducer ADM and a discoloration resin CBR. The discoloration resin CBR may be the same or different from the base resin BR. The sub-pattern layer S-BLP may serve as an adhesive layer. The sub-pattern layer S-BLP may be a single adhesive layer. However, the embodiment of the inventive concept is not limited thereto, and like the pattern layer illustrated in FIG. 5A and FIG. 5B, the sub-pattern layer S-BLP may have a plurality of stacked structures including a transparent adhesive layer. The sub-pattern layer S-BLP may be disposed on a lower side of the base film layer BF to serve as a protection layer adhesive member which fixes the base film layer BF to the window WP.

The base film layer BF may be a polymer film including at least one polymer resin of polyethyleneterephthalate (PET), poly(butylene terephthalate) (PBT), polyethylene naphthalene (PEN), polycarbonate (PC), poly(methylmethacrylate (PMMA), polystyrene (PS), polyvinylchloride (PVC), polyethersulfone (PES), polypropylene (PP), polyamide (PA), modified polyphenylene ether (m-PPO), polyoxymethylene (POM), polysulfone (PSU), polyphenylene sulfide (PPS), polyimide (PI), polyethyleneimine (PEI), polyether ether ketone (PEEK), polyamide imide (PAI), polyarylate (PAR), or thermoplastic polyurethane (TPU). For example, in an embodiment, the base film layer BF may be a polyethyleneterephthalate (PET) film or a thermoplastic polyurethane (TPU) film. Also, the base film layer BF may be a polyethyleneterephthalate (PET) film not having a phase delay.

In an embodiment, the sub-pattern layer S-BLP may include the discoloration inducer ADM and the base film layer BF may not include a discoloration inducer. In an embodiment, the pattern layer BL-P (which includes a stacked structure of the sub-pattern layer S-BLP and the base film layer BF) may serve as a protection layer in a window module and a light blocking layer which defines the peripheral region NAA (e.g., see FIG. 3).

Referring to FIG. 7B, a pattern layer BL-Pa according to an embodiment may include a sub-pattern layer S-BLPa and a protection layer adhesive layer OCL-P. The sub-pattern layer S-BLPa is disposed on an upper side of the protection layer adhesive layer OCL-P and may serve as a protection layer. The pattern layer BL-Pa illustrated in FIG. 7B may correspond to an embodiment of the pattern layer BL-P in the window module WM-2 according to an embodiment illustrated in FIG. 6.

The sub-pattern layer S-BLPa may include a transparent portion TA-BLP including a discoloration inducer ADM and a base resin BR-P, and a discoloration portion BA-BLP including a discoloration inducer ADM and a discoloration resin CBR-P. As in other embodiments, the base resin BR-P and the discoloration resin CBR-P may be different resins, but may be the same resin in another embodiment. In the pattern layer BL-Pa according to an embodiment illustrated in FIG. 7B, the sub-pattern layer S-BLPa may serve as the base film layer BF of the pattern layer BL-P according to an embodiment illustrated in FIG. 7A. In the pattern layer BL-Pa according to an embodiment illustrated in FIG. 7B, the sub-pattern layer S-BLPa may be disposed on the upper side of the window WP (e.g., see FIG. 6) to protect the window WP (e.g., see FIG. 6) from adverse effects of the external environment.

The base resin BR-P and the discoloration resin CBR-P of the sub-pattern layer S-BLPa, which serve as a protection layer, may have high modulus and strength properties compared to the base resin BR (e.g., see 7A) and the discoloration resin CBR (see FIG. 7A) of the sub-pattern layer S-BLP, which serve as an adhesive layer.

In an embodiment illustrated in FIG. 7B, the pattern layer BL-Pa may include the protection layer adhesive layer OCL-P disposed on a lower side of the sub-pattern layer S-BLPa, and the protection layer adhesive layer OCL-P may include an optically clear adhesive (OCA). The protection layer adhesive layer OCL-P may include at least one of an acrylic adhesive, a silicone-based adhesive, or a urethane-based adhesive. The protection layer adhesive layer OCL-P may not include a discoloration inducer.

In an embodiment, the sub-pattern layer S-BLPa may serve as a protection layer to protect the window WP (e.g., see FIG. 6), and may serve as a light blocking layer which defines the peripheral region NAA (e.g., see FIG. 3).

In the window module WM-2 according to an embodiment illustrated in FIG. 6 to FIG. 7B, both the lower surface WP-BS and the upper surface WP-US of the window WP may be flat surfaces, e.g., continuously even surfaces which do not include a step, projection, or discontinuity. In addition, both the upper surface BL-US and the lower surface BL-BS of each of the pattern layers BL-P and BL-Pa may all be flat (continuously even or level) surfaces without a step. Accordingly, the window WP and the pattern layer BL may be coupled to each other without separation and may exhibit excellent reliability properties.

Meanwhile, the same content as the content described with respect to the transparent portion TA-BL and the discoloration portion BA-BL in the pattern layer BL (e.g., see FIG. 4) described with reference to FIG. 4 may be applied to the transparent portion TA-BL and the discoloration portion BA-BL of each of the sub-pattern layers S-BLP and S-BLPa of FIG. 7A and FIG. 7B.

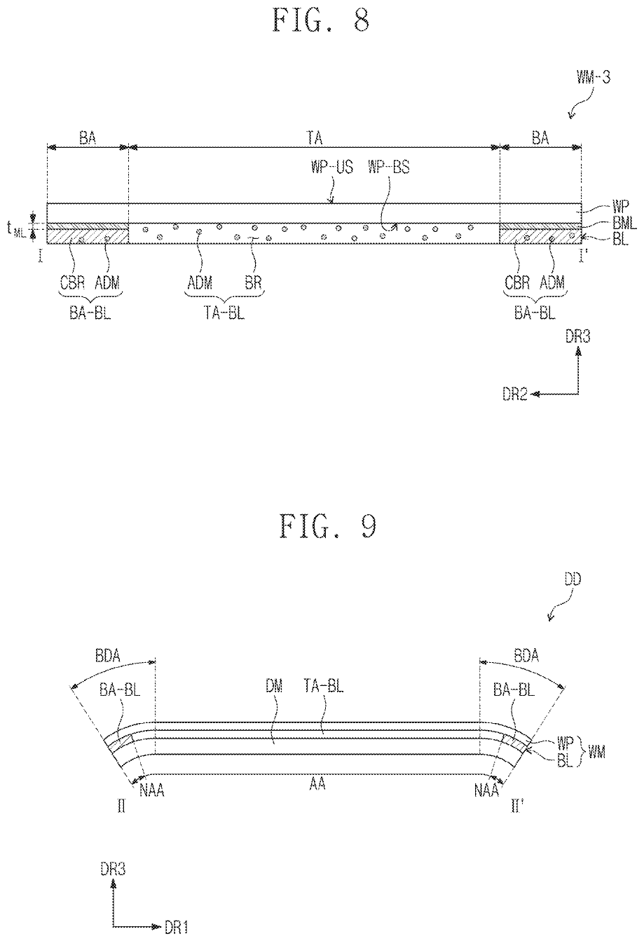

FIG. 8 is a cross-sectional view of a window module WM-3 according to an embodiment of the inventive concept. Referring to FIG. 8, the window module WM-3 according to an embodiment may further include a window WP and pattern layer BL, and may further include a light blocking pattern BML.

In an embodiment illustrated in FIG. 8, the pattern layer BL may be disposed in a lower portion of the window WP, and the light blocking pattern BML may be disposed between the window WP and at least a portion of the pattern layer BL on a window lower surface WP-BS. Meanwhile, unlike what is illustrated in FIG. 8, the light blocking pattern BML may be disposed on the window upper surface WP-US. The window module WM-3 according to an embodiment illustrated in FIG. 8 is different from the window module WM according to an embodiment described with reference to FIG. 4, in that the light blocking pattern BML is further included in the bezel region BA. The light blocking pattern BML may overlap a discoloration portion BA-BL of the pattern layer BL.

The light blocking pattern BML may be disposed in an edge region of the window WP. The light blocking pattern BML may be an ink print layer. In addition, the light blocking pattern BML may be formed to include a pigment or a dye.

The light blocking pattern BML may include a shielding ink for shielding light. For example, a shielding ink layer may include a base material and a shielding ink. The shielding ink may be carbon black particles. However, the embodiment of the inventive concept is not limited thereto, and the shielding ink may include one or more pigments, dyes, or mixtures thereof in addition to the carbon black particles.

In the window module WM-3 of an embodiment, components of the light blocking pattern BML and components of the discoloration portion BA-BL overlapping the light blocking pattern BML may prevent components inside the display module from being visually perceived externally. For example, the components of the light blocking pattern BML and the components of the discoloration portion BA-BL overlapping the light blocking pattern BML may be stacked and used to serve as a light blocking pattern layer.

In the window module WM-3 of an embodiment, the optical density of the pattern layer BL discoloration portion BA-BL may be less than a predetermined value, e.g., 3. Since the light blocking pattern BML is additionally introduced, the optical density of the pattern layer BL discoloration portion BA-BL in the window module WM-3 illustrated in FIG. 8 may be less than the optical density of the discoloration portion of the window module WM illustrated in FIG. 4. Even when the optical density is less than 3, the light blocking pattern BML and the discoloration portion BA-BL are overlapped, and thus may sufficiently serve as a light blocking pattern layer.

In addition, the light blocking pattern BML includes the pattern layer BL having the discoloration portion BA-BL. The light blocking pattern BML may have a thickness t_{ML} of, for example, 5 μm or less. The thickness of the light blocking pattern BML of the present invention is therefore significantly thinner than the thickness of about 15 μm of a light blocking pattern in other typical window modules that have been proposed and which do not include the pattern layer having a discoloration portion in accordance with one or more embodiments described herein. Therefore, the window module WM in accordance with one or more embodiments includes the pattern layer BL having the discoloration portion BA-BL having optical density which is controlled by the discoloration inducer ADM. As a result, the thickness of the light blocking pattern BML (disposed corresponding to the bezel region BA) may be reduced or minimized. Accordingly, the likelihood of a step (or other discontinuity) being formed between the window WP and the pattern layer BL may be minimized. As a result, the likelihood of a separation phenomenon occurring (that would otherwise occur if the step were included) may be reduced, and a display device of an embodiment may exhibit excellent display quality and reliability properties.

FIG. 9 is a cross-sectional view of a display device DD according to an embodiment of the inventive concept. More specifically, FIG. 9 is a cross-sectional view corresponding to line II-II′ of FIG. 2. Referring to FIG. 9, the display device DD of an embodiment may include a curved or bending portion BDA which is curved, bent, or inclined in a region adjacent to an edge portion. A portion adjacent to an active region AA in the first direction axis DR1 of the peripheral region NAA of the display device DD of an embodiment may be included in the bending portion BDA.

The same contents as described with reference to FIG. 1 to FIG. 8 may be applied to a display module DM, and a window module including a window WP and a pattern layer BL, in the display device DD of an embodiment illustrated in FIG. 9. For example, the same configuration as the window module described with reference to FIG. 4 to FIG. 8 may be applied to the configuration of the window module WM illustrated in FIG. 9.

As described above, the pattern layer BL included in the window module WM according to an embodiment includes a discoloration portion BA-BL having an optical density which is changed by a discoloration inducer. As such, use of a separate light blocking pattern or a light blocking pattern may be avoided in order to promote reduced or minimized thickness, e.g., the pattern layer BL and the window WP may be coupled to each other without separation in the display device DD. In addition, coupling properties of the pattern layer BL and the window WP may be equally applied to a curved portion such as the bending portion BDA, or to a portion of the display device in which the shape is deformed. Therefore, the display device DD of an embodiment may have an excellent coupling force between the window WP and the pattern layer BL, even in cases in which the shape is deformed. The display device DD may also exhibit excellent display quality and reliability properties since the lower structure of the display module DM is covered by the pattern layer BL and thus prevented from being visually recognized by a user.

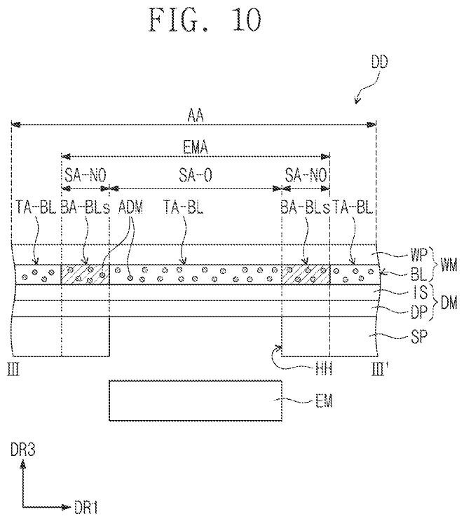

FIG. 10 is a cross-sectional view showing a portion of a display device of an embodiment. More specifically, FIG. 10 is a cross-sectional view corresponding to line III-III′ of FIG. 2. Moreover, FIG. 10 shows a portion of the active region AA in which the electronic module region EMA is defined.

Referring to FIG. 10, the pattern layer BL may further include a sub-discoloration portion BA-BLs. The sub-discoloration portion BA-BLs may include a discoloration inducer ADM. FIG. 10 shows only a portion corresponding to the electronic module region EMA, but as illustrated, for example, in FIG. 3 and FIG. 4, of the display device DD of an embodiment, the pattern layer BL includes the transparent portion TA-BL and the discoloration portion BA-BL. Here, it is shown that the transparent portion TA-BL may overlap the active region AA, and the discoloration portion BA-BL may overlap the peripheral region NAA. Thus, in an embodiment, the pattern layer BL may include the transparent portion TA-BL, the discoloration portion BA-BL, and the sub-discoloration portion BA-BLs.

Referring to FIG. 10, the sub-discoloration portion BA-BLs may be disposed to correspond to only a portion of the electronic module region EMA. Referring to FIG. 10, the electronic module region EMA may include a sensing portion SA-O overlapping a through-hole HH provided for the electronic module EM and included in a lower module SP. A peripheral portion SA-NO may surround the sensing portion SA-O. The sub-discoloration portion BA-BLs may be disposed to correspond to the peripheral portion SA-NO. The transparent portion TA-BL may be disposed in an area corresponding to the sensing portion SA-O. The transparent portion TA-BL, which may be disposed to correspond to the sensing portion SA-O, may also include the discoloration inducer ADM.

Because the sub-discoloration portion BA-BLs is disposed to correspond to the peripheral portion SA-NO surrounding the sensing portion SA-O, light leakage in the electronic module EM may be blocked, and a lower structure of the electronic module EM may be covered. In addition, the pattern layer BL including the sub-discoloration portion BA-BLs is provided without a step (or other discontinuity) at the boundary between the sub-discoloration portion BA-BLs and the transparent portion TA-BL between the window WP and the display module DM. As a result, the display device DD may have excellent coupling force with respect to the window WP. Therefore, the display device DD of an embodiment may exhibit excellent display quality and reliability properties, even in the electronic module region EMA, as a result of the pattern layer BL having the sub-discoloration portion BA-BLs.

In accordance with one or more of the embodiments described herein, a display device is provided to include a pattern layer having a discoloration portion whose optical density or light transmittance is changed by a discoloration inducer. The display device may therefore may exhibit excellent light blocking and covering properties, even when a light blocking pattern layer is excluded or the thickness of the light blocking pattern layer is minimized. As a result, the display device may generate images with excellent display quality.

In addition, the display device in accordance with one or more embodiments includes the pattern layer having the discoloration portion. As a result, the display device may exhibit excellent reliability since a separation phenomenon caused by a step between the pattern layer and a member adjacent to an upper portion or a lower portion of the pattern layer is reduced or minimized. In addition, the discoloration portion of the pattern layer may be formed after a process of ultraviolet-curing of an adhesive layer or the like, and thus may exhibit properties which reduce the likelihood of a degradation in adhesion force from occurring due to uncuring.

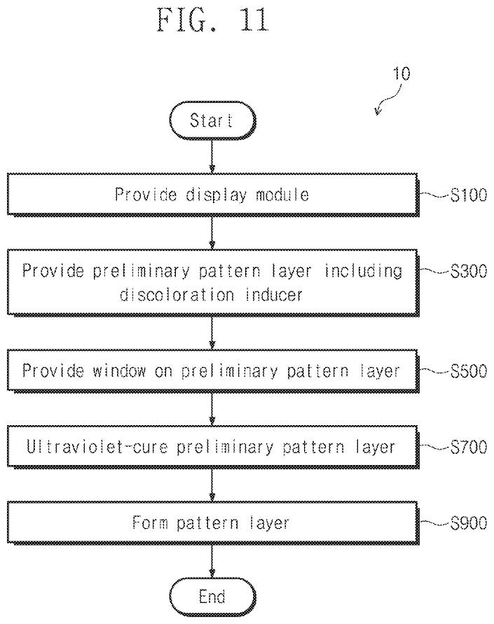

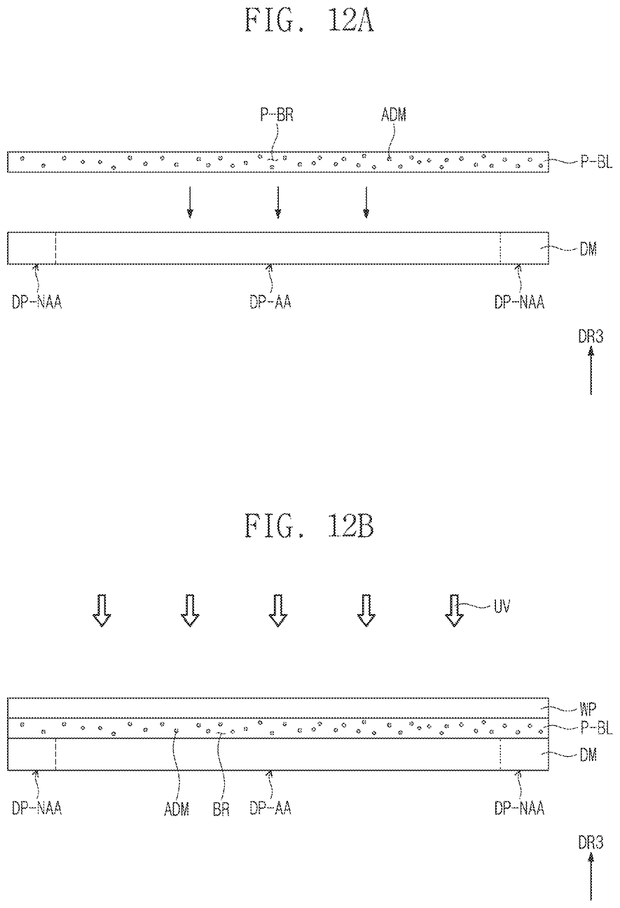

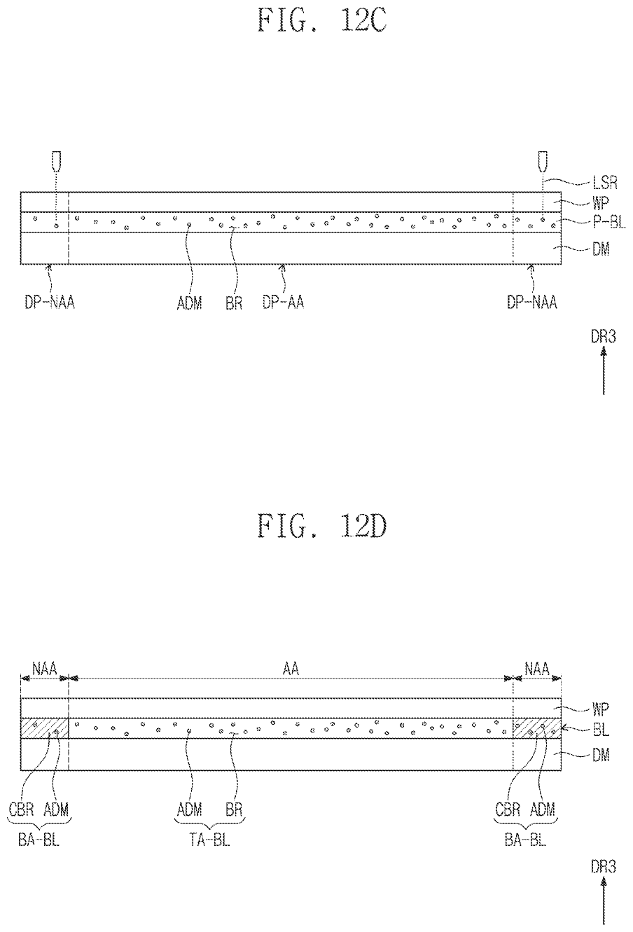

Hereinafter, with reference to FIG. 11 to FIG. 12D, embodiments of a method 10 for manufacturing a display device will be described. FIG. 11 is a flowchart showing a method for manufacturing a display device of embodiments of the inventive concept. FIG. 12A to FIG. 12D are schematically show various operations of the method.

Referring to FIG. 11, the display device manufacturing method 10 may include providing a display module S100, providing a preliminary pattern layer including a discoloration inducer S300, providing a window on the preliminary pattern layer S500, and forming a pattern layer S900. In addition, the display device manufacturing method 10 may include performing curing (e.g., ultraviolet-curing) on the preliminary pattern layer S700 between the operation of providing of the window on the preliminary pattern layer S500 and the forming of the pattern layer S900.

A display module provided in the providing of the display module S100 may include a display panel, an input sensor, or the like. In addition, in an embodiment, the display module may further include an optical layer such as a polarizing plate disposed on the input sensor.

FIG. 12A is a view showing an example of operation S300 of providing the preliminary pattern layer including the discoloration inducer. In operation S300, a preliminary pattern layer P-BL may be provided on a display module DM. The display module DM may include an active region DP-AA and a peripheral region DP-NAA. The preliminary pattern layer P-BL may include a discoloration inducer ADM. In addition, the preliminary pattern layer P-BL may include a first base resin P-BR. The first base resin P-BR may include at least one of an acrylic resin, a polyethylene-based resin, a silicone-based resin, or a urethane-based resin. The first base resin P-BR may have been cured or may be an uncured resin requiring an additional curing process. When the first base resin P-BR is an uncured resin, performing ultraviolet-curing on the preliminary pattern layer S700 may be added after the operation of providing the window on the preliminary pattern layer S500.

When the first base resin P-BR is a resin that has been cured, performing ultraviolet-curing on the preliminary pattern layer S700 may be omitted. Thus, the operation of forming the pattern layer S900 may be performed after the operation of providing the window on the preliminary pattern layer S500.

FIG. 12B is a view showing a case in which ultraviolet-curing on the preliminary pattern layer S700 is performed after the operation of providing the window on the preliminary pattern layer S500. When the first base resin P-BR (e.g., see FIG. 12A) is an uncured resin, the first base resin P-BR (e.g., see FIG. 12A) may be changed into a cured base resin BR by applying ultraviolet rays UV through window WP. In performing the ultraviolet-curing on the preliminary pattern layer S700, the ultraviolet rays UV may be provided to the entire active region DP-AA and the entire peripheral region DP-NAA of the display module DM. Accordingly, the first base resin P-BR (e.g., see FIG. 12A) of the preliminary pattern layer P-BL (e.g., see FIG. 12A) corresponding to each of the active region DP-AA and the peripheral region DP-NAA is uniformly further cured. As a result, the preliminary pattern layer P-BL may include a sufficiently cured base resin BR even in a portion corresponding to the peripheral region DP-NAA.

In one embodiment, the display device manufacturing method 10 may further include removing voids using autoclave equipment after the operation of providing the window on the preliminary pattern layer S500. When the display device manufacturing method 10 of an embodiment includes performing ultraviolet-curing on the preliminary pattern layer S700, removing the voids using the autoclave equipment may be performed before performing ultraviolet-curing on the preliminary pattern layer S700. In the display device manufacturing method 10, voids introduced during a process of attaching the window WP and the preliminary pattern layer P-BL may be additionally removed using the autoclave equipment.

FIG. 12C and FIG. 12D are views schematically showing the operation of forming the pattern layer S900. Forming the pattern layer S900 may include an operation of irradiating a laser LSR onto the preliminary pattern layer P-BL, thereby forming the pattern layer BL including a discoloration portion BA-BL (whose optical density has been increased by the discoloration inducer ADM) and a transparent portion TA-BL having a lower optical density than the discoloration portion BA-BL.

The display module DM includes the active region DP-AA and the peripheral region DP-NAA disposed on at least one side of the active region DP-AA. The laser LSR may be irradiated onto the preliminary pattern layer P-BL in correspondence to the peripheral region DP-NAA. The preliminary pattern layer P-BL includes the base resin BR and the discoloration inducer ADM dispersed in the base resin BR. The discoloration inducer ADM, which is activated by the laser LSR in forming the pattern layer S900, may change the light transmittance of the base resin BR to form the pattern layer BL including the discoloration portion BA-BL. The discoloration portion BA-BL may include the discoloration inducer ADM and a discoloration resin CBR modified from the base resin BR.

The laser LSR used in forming the pattern layer S900 may be, for example, an Nd:YAG laser. The power of the laser LSR provided to the preliminary pattern layer P-BL, the moving speed of the laser LSR, the frequency of the laser LSR, and/or other parameters may be adjusted according to optical properties of the discoloration portion BA-BL. For example, in order to prepare a discoloration portion BA-BL with a high optical density, the laser LSR may be set to have high frequency and low movement speed. For example, the laser LSR used in forming the pattern layer S900 may have a power of 8 W to 16 W and a frequency of 10 kHz to 40 kHz, using an Nd:YAG laser of 1064 nm. The laser LSR may be provided to correspond to the peripheral region DP-NAA and, for example, may be provided while being moved at a speed of 100 mm/s to 400 mm/s. The laser has been described as a Nd:YAG laser, but a different laser may be used in other embodiments.

A method for manufacturing a display device of an embodiment includes providing a pattern layer having a discoloration portion whose optical density or light transmittance is changed by a discoloration inducer. As a result, a display device exhibiting having excellent light blocking and covering properties may be manufactured, even when a light blocking pattern layer is excluded or the thickness of the light blocking pattern layer is reduced or minimized. In addition, the method for manufacturing a display device of an embodiment includes using a laser to form a pattern layer including a discoloration portion. This may result in manufacturing a display device with a reduced likelihood of a separation phenomenon occurring, which phenomenon may otherwise occur by formation of step between the pattern layer and a member adjacent to an upper portion or a lower portion of the pattern layer. As a result, degradation in adhesion force due to uncuring is reduced.

In accordance with one or more embodiments described herein, a display device includes a window and a pattern layer disposed in an upper portion or a lower portion of the window. The pattern layer may include a discoloration portion and a transparent portion which have different light transmittances. Thus, the display device may exhibit excellent display quality, since a peripheral region is sufficiently covered even when a light blocking pattern is excluded. In addition, the display device of an embodiment may reduce or minimize the formation of a step between one surface of the window and one surface of a neighboring pattern layer. This may reduce the likelihood of a separation phenomenon occurring between the two layers, and thus produce excellent reliability properties.

Furthermore, a display device in accordance with one or more embodiments may exhibit excellent display quality and improved reliability as a result of including a pattern layer having a discoloration inducer which is activated by a laser. As a result, use of a light blocking pattern separately provided on one surface of a window may be excluded.

Furthermore, in accordance with one or more embodiments, a method for manufacturing a display device provides a laser to form a pattern layer including a discoloration portion with an increased optical density. Such a method may produce a display device having good display quality and improved reliability without having to introduce a separate light blocking pattern.

Although the present invention has been described with reference to preferred embodiments of the present invention, it will be understood by those skilled in the art that various modifications and changes in form and details may be made therein without departing from the spirit and scope of the present invention as set forth in the following claims. Accordingly, the technical scope of the present invention is not intended to be limited to the contents set forth in the detailed description of the specification, but is intended to be defined by the appended claims. The embodiments described herein may be combined to form additional embodiments.

What is claimed is:

1. A display device comprising:
a display module including an active region, and a peripheral region disposed on at least one side of the active region; and
a window module disposed on the display module, wherein the window module includes:
a window; and
a pattern layer adjacent to the window and overlapping the active region and the peripheral region, the pattern layer including a transparent portion and a discoloration portion, the discoloration portion having a light transmittance lower than a light transmittance of the transparent portion, wherein the transparent portion and the discoloration portion include a discoloration inducer activated by a laser.

2. The display device of claim 1, wherein the discoloration inducer comprises at least one of an organic pigment, an inorganic pigment, or a metal oxide.

3. The display device of claim 1, wherein the pattern layer comprises 0.05 wt % to 5 wt % of the discoloration inducer based on a total weight of the pattern layer.

4. The display device of claim 1, wherein:
the transparent portion comprises a base resin; and
the discoloration portion comprises a discoloration resin modified from the base resin.

5. The display device of claim 1, wherein the pattern layer is a single adhesive layer disposed between the display module and the window.

6. The display device of claim 1, wherein the pattern layer comprises:
a sub-pattern layer including the transparent portion and the discoloration portion; and
a transparent adhesive layer disposed on at least one of an upper surface or a lower surface of the sub-pattern layer, and excluding the discoloration inducer.

7. The display device of claim 6, wherein the sub-pattern layer is a single adhesive layer.

8. The display device of claim 1, wherein:
an optical density of the discoloration portion is 1 to 3, and
an optical density of the transparent portion is less than 1.

9. The display device of claim 1, wherein:
the pattern layer is disposed in an upper portion of the window; and
the window module further comprises a window adhesive layer disposed between the display module and the window.

10. The display device of claim 9, wherein the pattern layer comprises:
a sub-pattern layer including the transparent portion and the discoloration portion; and
a base film layer disposed on an upper surface of the sub-pattern layer, and excluding the discoloration inducer.

11. The display device of claim 9, wherein the pattern layer comprises:
a sub-pattern layer including the transparent portion and the discoloration portion; and
a protection layer adhesive layer disposed between the sub-pattern layer and the window, and excluding the discoloration inducer.

12. The display device of claim 1, wherein the window module comprises:
a light blocking pattern disposed on an upper surface or a lower surface of the window, and overlapping the discoloration portion.

13. A display device comprising:
an electronic module;
a display module disposed on the electronic module and including an active region, an electronic module region overlapping the electronic module and included in the active region, and a peripheral region disposed on at least one side of the active region; and
a window module disposed on the display module and including a window and a pattern layer adjacent to the window, the pattern layer including a discoloration inducer activated by a laser, wherein the pattern layer includes:
a transparent portion corresponding to the active region; and
a discoloration portion corresponding to the peripheral region and having a higher optical density than the transparent portion.

14. The display device of claim 13, wherein the pattern layer overlaps the electronic module region, includes the discoloration inducer, and further includes a sub-discoloration portion having a higher optical density than the transparent portion.

15. The display device of claim 13, wherein the discoloration inducer comprises at least one of an organic pigment, an inorganic pigment, or a metal oxide.

16. A method for manufacturing a display device, the method comprising:
providing a display module;
providing a preliminary pattern layer including a discoloration inducer on the display module;
providing a window on the preliminary pattern layer; and
irradiating a laser onto the preliminary pattern layer to form a pattern layer including a discoloration portion and a transparent portion, the discoloration portion having an increased optical density by the discoloration inducer and the transparent portion having an optical density lower than the discoloration portion.

17. The method of claim 16, further comprising:
before the forming of the pattern layer, performing ultraviolet-curing on the preliminary pattern layer.

18. The method of claim 16, wherein the display module comprises:
an active region; and
a peripheral region disposed on at least one side of the active region,
wherein in forming the pattern layer, the laser is irradiated onto the peripheral region.

19. The method of claim 16, wherein:
the preliminary pattern layer comprises a base resin and the discoloration inducer dispersed in the base resin; and
forming the pattern layer comprises changing light transmittance of the base resin by the discoloration inducer activated by the laser, thereby forming the discoloration portion.

20. The method of claim 16, wherein the laser is an Nd:YAG laser.
